(19) United States
(12) Patent Application Publication
(10) Pub. No.: US 2024/0237342 A1
(43) Pub. Date: Jul. 11, 2024

(54) SEMICONDUCTOR MEMORY DEVICE AND METHOD OF MANUFACTURING THE SEMICONDUCTOR MEMORY DEVICE

(71) Applicant: SK hynix Inc., Icheon-si Gyeonggi-do (KR)

(72) Inventors: Dong Uk LEE, Icheon-si Gyeonggi-do (KR); Hae Chang YANG, Icheon-si Gyeonggi-do (KR)

(73) Assignee: SK hynix Inc., Icheon-si Gyeonggi-do (KR)

(21) Appl. No.: 18/349,735

(22) Filed: Jul. 10, 2023

(30) Foreign Application Priority Data
Jan. 10, 2023 (KR) 10-2023-0003453

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor memory device and a method of manufacturing the semiconductor memory device are provided. The semiconductor memory device includes a first stacked structure including a plurality of first electrode patterns and a plurality of first interlayer insulating layers that are alternately stacked on each other, a first vertical structure extending into the first stacked structure in a vertical direction, an insulating layer formed over the first stacked structure, a coupling structure passing through the insulating layer and formed over the first vertical structure, a second stacked structure including a plurality of second electrode patterns and a plurality of second interlayer insulating layers that are alternately stacked on each other over the insulating layer, and a second vertical structure extending into the second stacked structure in the vertical direction and formed over the coupling structure.

### CROSS-REFERENCE TO RELATED APPLICATION

The present application claims priority under 35 U.S.C. § 119(a) to Korean patent application number 10-2023-0003453, filed on Jan. 10, 2023, in the Korean Intellectual Property Office, the entire disclosure of which is incorporated herein by reference.

### BACKGROUND

### 1. Technical Field

Various embodiments of the present disclosure generally relate to an electronic device, and more particularly, to a three-dimensional semiconductor memory device and a manufacturing method of the three-dimensional semiconductor memory device.

### 2. Related Art

Non-volatile memory devices retain stored data even in the absence of supplied power. Due to the limitations in increasing the integration density of two-dimensional non-volatile memory devices in which memory cells are formed in a single layer over a substrate, three-dimensional non-volatile memory devices have been proposed in which memory cells are stacked in a vertical direction over a substrate.

A three-dimensional non-volatile memory device may include interlayer insulating layers and gate electrodes that are stacked alternately with each other, and channel layers that pass through the interlayer insulating layers and the gate electrodes, and memory cells may be stacked along the channel layers. Various structures and manufacturing methods have been developed to improve the operational reliability and manufacturing yield of the three-dimensional non-volatile memory device having the above-described configuration.

### SUMMARY

According to an embodiment of the present disclosure, a semiconductor memory device may include a first stacked structure including a plurality of first electrode patterns and a plurality of first interlayer insulating layers that are alternately stacked on each other, a first vertical structure extending into the first stacked structure in a vertical direction, an insulating layer formed over the first stacked structure, a coupling structure passing through the insulating layer and formed over the first vertical structure, a second stacked structure including a plurality of second electrode patterns and a plurality of second interlayer insulating layers that are alternately stacked on each other over the insulating layer, and a second vertical structure extending into the second stacked structure in the vertical direction and formed over the coupling structure, wherein each of the first vertical structure, the coupling structure, and the second vertical structure includes an impurity, and wherein a concentration of the impurity of the coupling structure varies depending on proximity to one of the first vertical structure and the second vertical structure.

According to an embodiment of the present disclosure, a semiconductor memory device may include a first vertical structure including a first core layer and a first channel layer, the first core layer extending in a vertical direction, the first channel layer surrounding a sidewall of the first core layer, a second vertical structure disposed over the first vertical structure and including a second core layer and a second channel layer, the second core layer extending in the vertical direction, the second channel layer surrounding a sidewall of the second core layer, and a coupling structure disposed between the first vertical structure and the second vertical structure and including a third core layer and a coupling channel layer, the coupling channel layer surrounding a sidewall of the third core layer, wherein a concentration of an impurity of the coupling channel layer is higher than a concentration of an impurity of each of the first channel layer and the second channel layer.

According to an embodiment of the present disclosure, a method of manufacturing a semiconductor memory device may include forming a first stacked structure by stacking first material layers and second material layers alternately with each other, forming first channel holes that pass through the first stacked structure in a vertical direction and forming a first channel layer that includes an impurity and is disposed on a sidewall of each of the first channel holes, forming an insulating layer that is disposed over the first stacked structure and the first channel layer and forming coupling holes that pass through the insulating layer and expose the first channel layer, forming a coupling channel layer on a sidewall of each of the coupling holes, wherein a lower part of the coupling channel layer is formed to be in contact with an upper surface of the first channel layer, injecting the impurity into the coupling channel layer by performing an ion implantation process, forming a second stacked structure by stacking third material layers and fourth material layers alternately with each other over the insulating layer and the coupling channel layer; and forming second channel holes that pass through the second stacked structure in the vertical direction and expose an upper surface of the coupling channel layer and forming a second channel layer that includes the impurity and is disposed on a sidewall of each of the second channel holes, wherein, in injecting the impurity into the coupling channel layer, the ion implantation process is performed such that a concentration of the impurity of the coupling channel layer is higher than a concentration of the impurity of each of the first channel layer and the second channel layer.

### BRIEF DESCRIPTION OF THE DRAWINGS

FIG. 1 is a block diagram illustrating a semiconductor memory device according to an embodiment;

FIG. 2 is a diagram illustrating three-dimensionally structured memory blocks;

FIG. 3 is a cross-sectional diagram of a memory string shown in FIG. 2;

FIGS. 4A and 4B are diagrams illustrating an impurity concentration of a channel included in a memory string ;

FIGS. 5A, 5B, 5C, 5D, 5E, and 5F are cross-sectional diagrams illustrating a method of manufacturing a semiconductor memory device according to an embodiment;

FIG. 6 is a block diagram illustrating a memory system including the semiconductor memory device shown in FIG. 1;

FIG. 7 is a block diagram illustrating an example of application of the memory system shown in FIG. 6; and

FIG. 8 is a block diagram illustrating a computing system including the memory system described above with reference to FIG. 7.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Various embodiments are directed to a semiconductor memory device capable of improving electrical characteristics of a coupling portion between a lower cell portion and an upper cell portion of a memory string and a method of manufacturing the semiconductor memory device.

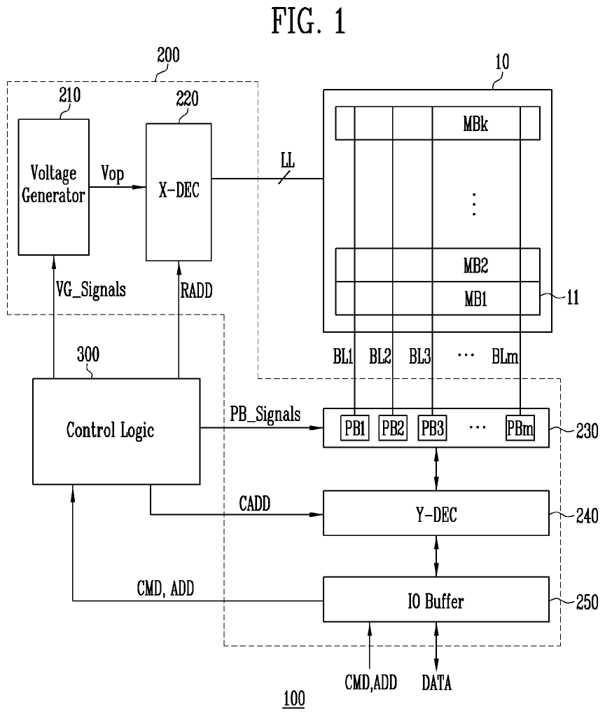

FIG. 1 is a block diagram illustrating a semiconductor memory device 100 according to an embodiment.

Referring to FIG. 1, the semiconductor memory device 100 may be configured to include a memory cell array 10, a voltage generator 210, an X-decoder (X-DEC) 220, a read and write circuit 230, a Y-decoder (Y-DEC) 240, an input/output buffer (IO Buffer) 250, and control logic 300. The voltage generator 210, the X-decoder 220, the read and write circuit 230, the Y-decoder 240, and the input/output buffer 250 may be defined as a peripheral circuit 200 that performs a program operation, a read operation, and an erase operation on the memory cell array 10.

The memory cell array 10 may include a plurality of memory blocks MB1 to MBk. The plurality of memory blocks MB1 to MBk may be coupled to the X-decoder 220 through local lines LL. The plurality of memory blocks MB1 to MBk may be coupled to the read and write circuit 230 through bit lines BL1 to BLm. Each of the plurality of memory blocks MB1 to MBk may include a plurality of memory cells. According to an embodiment, the plurality of memory cells may be non-volatile memory cells.

Each of the memory blocks MB1 to MBk of the memory cell array 10 may include a plurality of memory strings. Each of the plurality of memory strings may include a drain select transistor, a plurality of memory cells, and a source select transistor coupled in series between a bit line and a source line. In addition, each of the plurality of memory strings may include pass transistors each between the source select transistor and the memory cells and between the drain select transistor and the memory cells. The memory cell array 10 will be described in detail below.

The voltage generator 210 may generate various operating voltages Vop in response to voltage generation control signals VG_Signals output from the control logic 300. For example, the voltage generator 210 may generate a program voltage and a pass voltage during a program operation and a read voltage and a pass voltage during a read operation.

In response to a row address RADD output from the control logic 300, the X-decoder 220 may apply the various operating voltages Vop generated by the voltage generator 210 to the local lines LL coupled to a selected memory block from among the plurality of memory blocks MB1 to MBk included in the memory cell array 10. For example, the X-decoder 220 may apply the program voltage generated by the voltage generator 210 during the program operation to a selected word line from among the local lines LL coupled to the selected memory block and apply the pass voltage to unselected word lines except for the selected word line among the local lines LL. In addition, the X-decoder 220 may apply the read voltage generated by the voltage generator 210 during the read operation to the selected word line from among the local lines LL coupled to the selected memory block and apply the pass voltage to the unselected word lines except for the selected word line among the local lines LL.

The read and write circuit 230 may include a plurality of page buffers PB1 to PBm. The plurality of page buffers PB1 to PBm may be coupled to the memory cell array 10 through the bit lines BL1 to BLm. Each of the plurality of page buffers PB1 to PBm may temporarily store data DATA to be programmed which is received through the input/output buffer 250 and the Y-decoder 240 during the program operation and may adjust potential levels of the bit lines BL1 to BLm based on the temporarily stored data DATA. For example, when the data DATA to be programmed is “1”, each of the plurality of page buffers PB1 to PBm may apply a program inhibition voltage (for example, Vcc) to a corresponding bit line; when the data DATA to be programmed is “0”, each of the plurality of page buffers PB1 to PBm may apply a program permission voltage (having a lower voltage level than Vcc, for example, 0 V) to a corresponding bit line. In addition, each of the plurality of page buffers PB1 to PBm may precharge the bit lines BL1 to BLm to a set level during the read operation, and after precharging the bit lines BL1 to BLm, each of the plurality of page buffers PB1 to PBm may perform the read operation by sensing potential levels or amounts of current of the bit lines BL1 to BLm when the read voltage is applied to the selected memory block.

The read and write circuit 230 may be controlled in response to page buffer control signals PB_Signals generated by the control logic 300.

The input/output buffer 250 may receive a command CMD and an address ADD from an external device, transmit, to the control logic 300, the received command CMD and address ADD, and transmit, to the Y-decoder 240, the data DATA to be programmed that is received from the external device during the program operation. In addition, the input/output buffer 250 may receive the data DATA read from the Y-decoder 240 and output the received data DATA to the external device during the read operation.

In response to a column address CADD received from the control logic 300, the Y-decoder 240 may transmit, to the read and write circuit 230, the data DATA to be programmed that is received from the input/output buffer 250 during the program operation, and may transmit, to the input/output buffer 250, the data DATA read from the read and write circuit 230 during the read operation.

The control logic 300 may be coupled to the voltage generator 210, the X-decoder 220, the read and write circuit 230, the Y-decoder 240, and the input/output buffer 250. The control logic 300 may be configured to control the general operations of the semiconductor memory device 100 in response to the command CMD received from the input/output buffer 250. For example, the control logic 300 may receive the command CMD corresponding to the program operation, the read operation, or the erase operation, and control the peripheral circuit 200 to perform the program operation, the read operation, or the erase operation in response to the received command CMD. In other words, the control logic 300 may receive the command CMD and the address ADD, generate and output the voltage generation control signals VG_Signals and the page buffer control signals PB_Signals in response to the received command CMD, generate the row address RADD and the column address CADD based on the address ADD, and output the generated row address RADD and the generated column address CADD to the X-decoder 220 and the Y-decoder 240, respectively.

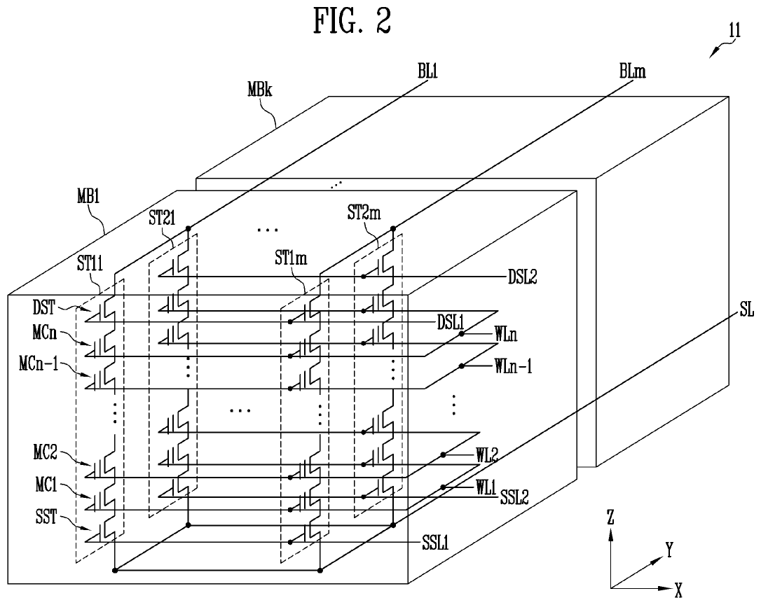

FIG. 2 is a diagram illustrating three-dimensionally structured memory blocks.

Referring to FIG. 2, the memory cell array 10 may include a plurality of memory blocks (MB1 to MBk) 11. Each of the memory blocks 11 may include a plurality of memory strings ST11 to ST1m and ST21 to ST2m. Each of the plurality of memory strings ST11 to ST1m and ST21 to ST2m may extend in a vertical direction (a Z direction). In the memory block 11, m memory strings may be arranged in a row direction (an X direction). FIG. 2 illustrates two memory strings arranged in a column direction (a Y direction) for convenience of illustration. However, three or more memory strings may be arranged in the column direction (the Y direction).

Each of the plurality of memory strings ST11 to ST1m and ST21 to ST2m may include at least one source select transistor SST, first to nth memory cells MC1 to MCn, and at least one drain select transistor DST.

The source select transistor SST of each memory string may be coupled between a source line SL and the memory cells MC1 to MCn. Source select transistors of memory strings arranged in the same row may be coupled to the same source select line. According to an embodiment, the source select transistors SST of the memory strings ST11 to ST1m arranged in the first row may be coupled to a first source select line SSL1. The source select transistors SST of the memory strings ST21 to ST2m arranged in the second row may be coupled to a second source select line SSL2. Alternatively, according to another embodiment, source select transistors of the memory strings ST11 to ST1m and ST21 to ST2m may be coupled in common to a single source select line.

The first to nth memory cells MC1 to MCn of each memory string may be coupled in series between the source select transistor SST and the drain select transistor DST. Gates of the first to nth memory cells MC1 to MCn may be coupled to first to nth word lines WL1 to WLn in a one-to-one manner.

According to an embodiment, at least one of the first to nth memory cells MC1 to MCn may serve as a dummy memory cell. When the dummy memory cell is provided, in an embodiment, a voltage or a current of a corresponding memory string may be stably controlled. Accordingly, in an embodiment, the reliability of data stored in the memory block 11 may be improved.

The drain select transistor DST of each memory string may be coupled between a bit line and the memory cells MC1 to MCn. The drain select transistors DST of the memory strings arranged in the row direction may be coupled to a drain select line extending in the row direction. According to an embodiment, the drain select transistors DST of the memory strings ST11 to ST1m in the first row may be coupled to a first drain select line DSL1. The drain select transistors DST of the memory strings ST21 to ST2m in the second row may be coupled to a second drain select line DSL2.

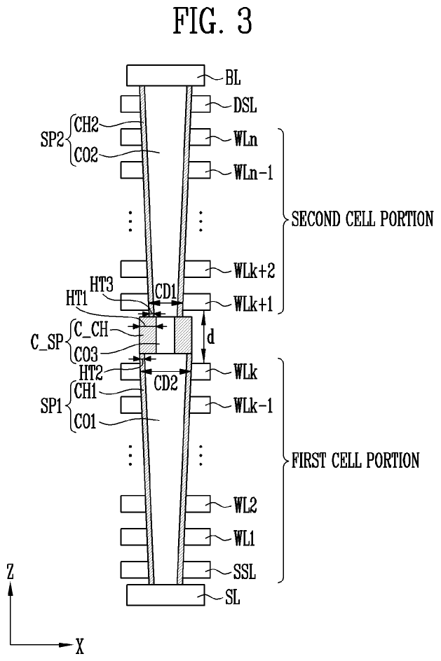

FIG. 3 is a cross-sectional diagram of a memory string shown in FIG. 2.

Referring to FIG. 3, the source line SL may be formed over a semiconductor substrate. A first vertical structure SP1, a coupling structure C_SP, and a second vertical structure SP2 may be sequentially stacked and formed over the source line SL. An upper part of the second vertical structure SP2 may be coupled to the bit line BL.

The first vertical structure SP1 may include a first core layer CO1 extending in the vertical direction and a first channel layer CH1 surrounding a sidewall of the first core layer CO1. The first channel layer CH1 may include polysilicon having an impurity. The impurity may include arsenic (As) or phosphorus (P). A plurality of conductive layers may be formed to surround the first channel layer CH1 at different levels and the plurality of conductive layers may be defined as a source select line SSL and the plurality of word lines WL1 to WLk. The first vertical structure SP1, the source select line SSL, and the plurality of word lines WL1 to WLk may be defined as a first cell portion of the memory string.

The second vertical structure SP2 may include a second core layer CO2 extending in the vertical direction and a second channel layer CH2 surrounding a sidewall of the second core layer CO2. The second channel layer CH2 may include polysilicon having an impurity. The impurity may include arsenic (As) or phosphorus (P). A plurality of conductive layers may be formed to surround the second channel layer CH2 at different levels and the plurality of conductive layers may be defined as a drain select line DSL and the plurality of word lines WLk+1 to WLn. The second vertical structure SP2, the drain select line DSL, and the plurality of word lines WLk+1 to WLn may be defined as a second cell portion of the memory string.

In other words, the first cell portion may include a plurality of memory cells corresponding to the plurality of word lines WL1 to WLk and a source select transistor and the second cell portion may include a plurality of memory cells corresponding to the plurality of word lines WLk+1 to WLn and a drain select transistor.

The first vertical structure SP1 may have a structure in which a width CD2 of an upper part of the first vertical structure SP1 is greater than a width of a lower part of the first vertical structure SP1. The second vertical structure SP2 may also have a structure in which a width of an upper part of the second vertical structure SP2 is greater than a width CD1 of a lower part of the second vertical structure SP2. In addition, the width CD2 of the upper part of the first vertical structure SP1 may be greater than the width CD1 of the lower part of the second vertical structure SP2.

The coupling structure C_SP may be disposed between the first vertical structure SP1 and the second vertical structure SP2. The coupling structure C_SP may include a third core layer CO3 having a cylindrical shape and a coupling channel layer C_CH surrounding a sidewall of the third core layer CO3. The first vertical structure SP1 and the second vertical structure SP2 may be spaced apart from each other by a predetermined distance d by the coupling structure C_SP interposed therebetween. Accordingly, the memory cell corresponding to the word line WLk+1 of the second cell portion and the memory cell corresponding to the word line WLk of the first cell portion may be spaced apart from each other by the predetermined distance d. The word “predetermined” as used herein with respect to a parameter, such as a predetermined distance, predetermined depth, or predetermined region, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The coupling channel layer C_CH may include polysilicon having an impurity. The impurity may include arsenic (As) or phosphorus (P). A concentration of the impurity in the coupling channel layer C_CH may vary depending on program order in the memory string. For example, an impurity concentration of a region of the coupling channel layer C_CH which is adjacent to the first vertical structure SP1 may be different from an impurity concentration of another region of the coupling channel layer C_CH which is adjacent to the second vertical structure SP2. For example, the impurity concentration in the coupling channel layer C_CH may linearly and gradually increase or decrease in the vertical direction.

The impurity concentration of the coupling channel layer C_CH may be higher than an impurity concentration of each of the first channel layer CH1 and the second channel layer CH2. In addition, a thickness HT1 of the coupling channel layer C_CH in a horizontal direction may be greater than a thickness HT2 of the first channel layer CH1 and a thickness HT3 of the second channel layer CH2 in the horizontal direction.

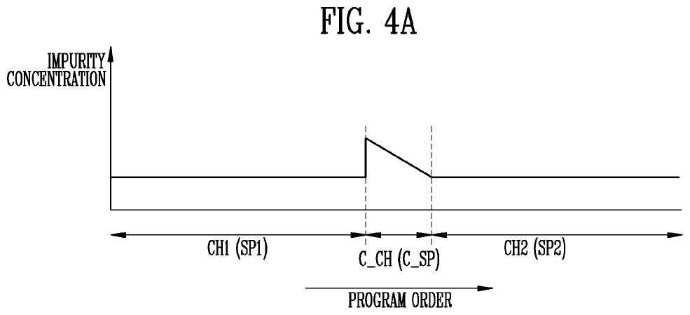

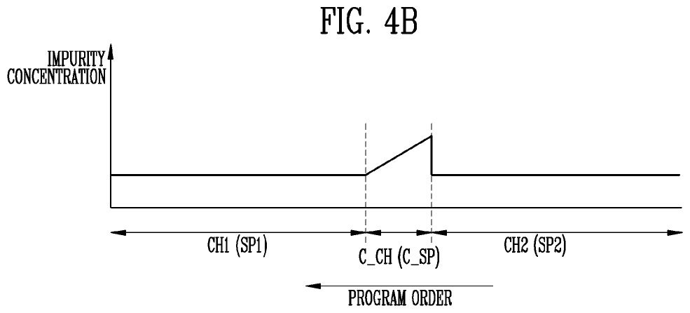

FIGS. 4A and 4B are diagrams illustrating an impurity concentration of a channel included in a memory string.

An impurity concentration of a coupling channel layer included in the memory string may vary depending on program order.

Referring to FIGS. 3 and 4A, when memory cells corresponding to the plurality of word lines WL1 to WLn are sequentially programmed from the memory cell corresponding to the word line WL1 adjacent to the source line SL to the memory cell corresponding to the word line WLn farthest away from the source line SL, the impurity concentration of the coupling channel layer C_CH of the coupling structure C_SP may become higher in a direction toward the first vertical structure SP1 and become lower in a direction toward the second vertical structure SP2. That is, the impurity concentration of the coupling channel layer C_CH of the coupling structure C_SP may be the highest in a portion in contact with the first channel layer CH1 of the first vertical structure SP1 and may gradually decrease as a level becomes higher in the vertical direction in the coupling structure C_SP.

Alternatively, referring to FIGS. 3 and 4B, when the memory cells corresponding to the plurality of word lines WL1 to WLn are sequentially programmed from the memory cell corresponding to the word line WLn adjacent to the bit line BL to the memory cell corresponding to the word line WL1 farthest away from the bit line BL, the impurity concentration of the coupling channel layer C_CH of the coupling structure C_SP may become higher in a direction toward the second vertical structure SP2 and become lower in a direction toward the first vertical structure SP1. That is, the impurity concentration of the coupling channel layer C_CH of the coupling structure C_SP may be the highest in a portion in contact with the second channel layer CH2 of the second vertical structure SP2 and may gradually decrease as a level becomes lower in the vertical direction in the coupling structure C_SP.

As described above, according to an embodiment, an impurity concentration of a coupling channel layer may be adjusted based on program order. In an embodiment, the conductance of an entire channel of the memory string may be improved by the impurity concentration of the coupling channel layer and a disturb phenomenon may be improved by adjusting the impurity concentration of the coupling channel layer based on the program order.

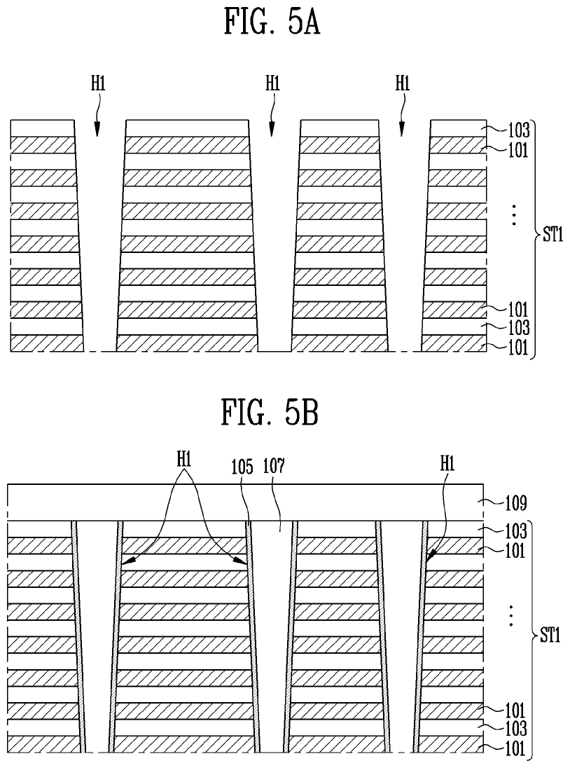

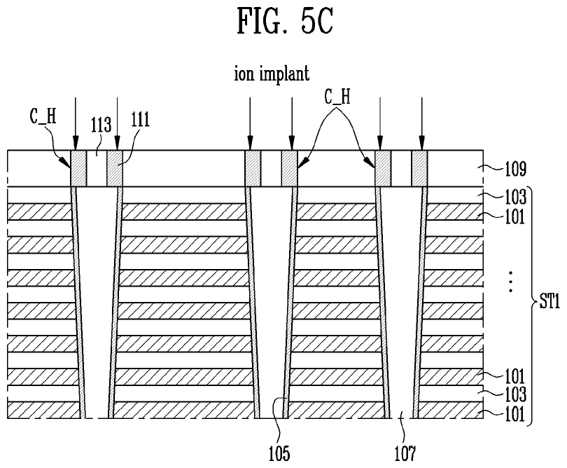

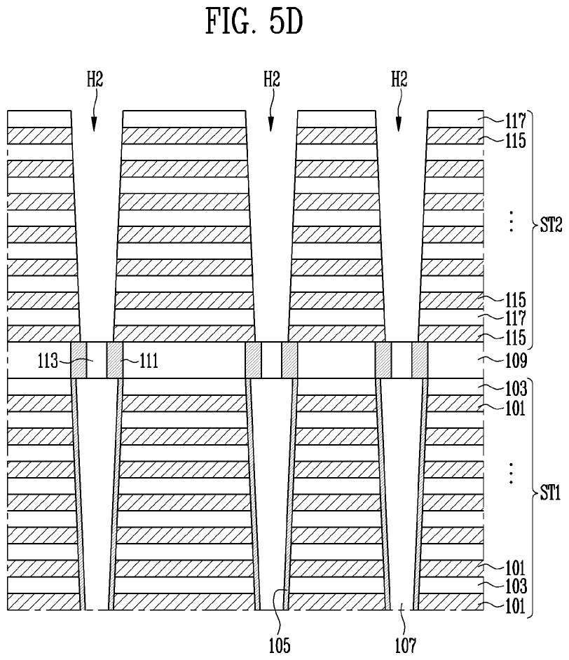

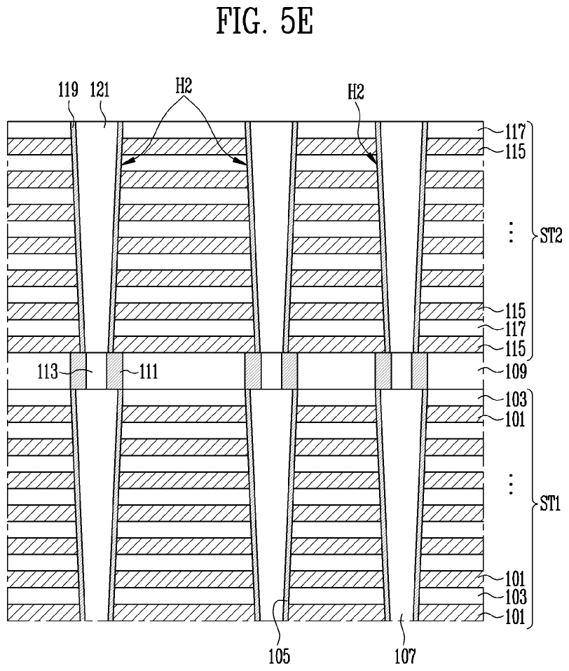

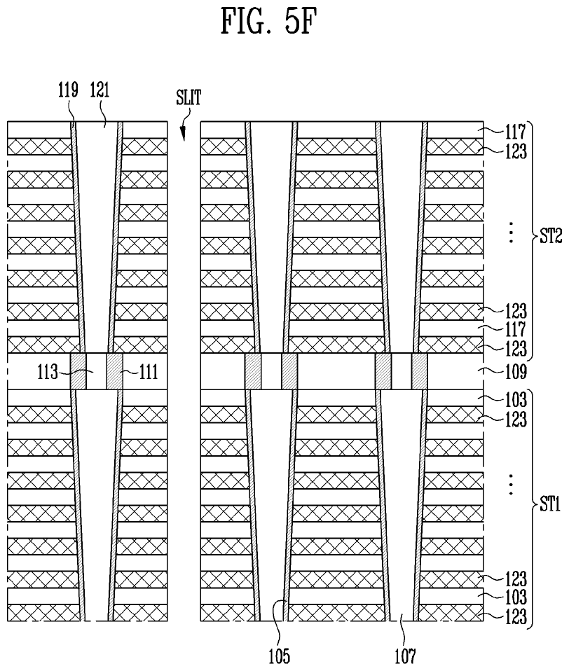

FIGS. 5A to 5F are cross-sectional diagrams illustrating a method of manufacturing a semiconductor memory device according to an embodiment.

Referring to FIG. 5A, a first stacked structure ST1 may be formed by stacking first material layers 101 and second material layers 103 alternately with each other over a lower structure (not shown). The first material layers 101 may include a different material from the second material layers 103.

According to an embodiment, the second material layers 103 may include an insulating material for a first interlayer insulating layer and the first material layers 101 may include a sacrificial material having a different etch rate from the second material layers 103. In the above-described embodiment, the second material layers 103 may include a silicon oxide layer and the first material layers 101 may include a silicon nitride layer. According to the above-described embodiment, the first material layers 101 may be replaced by electrode patterns and each of the second material layers 103 may remain as the first interlayer insulating layer in a subsequent process.

According to another embodiment, the second material layers 103 may include an insulating material for the first interlayer insulating layer and the first material layers 101 may include a conductive material for first electrode patterns. In the above-described other embodiment, the second material layers 103 may include a silicon oxide layer and the first material layers 101 may include one or more of a doped silicon layer, a metal silicide layer, a metal layer, and a metal nitride layer. In the above-described other embodiment, a process of replacing the first material layers 101 by electrode patterns may be skipped.

Subsequently, first channel holes H1 passing through the first stacked structure ST1 may be formed by partially etching the first material layers 101 and the second material layers 103.

Referring to FIG. 5B, a first channel layer 105 may be formed along a sidewall of each of the first channel holes H1. The first channel layer 105 may include polysilicon having an impurity. For example, the first channel layer 105 may be formed by depositing a polysilicon layer along the sidewall of each of the first channel holes H1, and dopant gas may be injected during a deposition process. The dopant gas may include arsenic (As) or phosphorus (P).

Subsequently, a first core layer 107 may be formed to fill a central part of each of the first channel holes H1. The first core layer 107 may include an oxide layer. The first channel layer 105 and the first core layer 107 may be defined as a first vertical structure.

Subsequently, an insulating layer 109 may be formed over the first stacked structure ST1 and the first vertical structures each including the first channel layer 105 and the first core layer 107. A thickness of the insulating layer 109 may be set considering the predetermined distance d shown in FIG. 3. The insulating layer 109 may include the same material as the second material layers 103.

A process of forming a memory layer (not shown) along the sidewall of each of the first channel holes H1 may be performed before the above-described process of forming the first channel layer 105 is performed. The memory layer (not shown) may include a charge trapping layer that is capable of trapping charges.

Referring to FIG. 5C, coupling holes C_H that pass through the insulating layer 109 and expose the first vertical structures each including the first channel layer 105 and the first core layer 107 may be formed. Subsequently, a coupling channel layer 111 may be formed along a sidewall of each of the coupling holes C_H. The coupling channel layer 111 may include polysilicon.

Subsequently, a third core layer 113 may be formed to fill a central part of each of the coupling holes C_H. The third core layer 113 may include an oxide layer.

Subsequently, an impurity may be injected into a predetermined region of the coupling channel layer 111 by performing an ion implantation process. The impurity may include arsenic (As) or phosphorus (P) and the impurity that is the same as the impurity included in the first channel layer 105 may be injected by the ion implantation process.

For example, when a portion which is adjacent to the first channel layer CH1 of the first vertical structure is formed to have a high impurity concentration as shown in FIG. 4A, the ion implantation process may be performed to target a lower region of the coupling channel layer 111, that is, a region in contact with the first channel layer 105. Alternatively, when a portion which is adjacent to the second channel layer CH2 of the second vertical structure is formed to have a high impurity concentration as shown in FIG. 4B, the ion implantation process may be performed to target an upper region of the coupling channel layer 111, that is, an upper surface and a portion having a predetermined depth from the upper surface of the coupling channel layer 111.

Subsequently, a heat treatment process may be performed to diffuse the impurity and to adjust an impurity concentration in the coupling channel layer 111 depending on a level in the coupling channel layer 111. For example, when the above-described ion implantation process is performed to inject the impurity to target the lower region of the coupling channel layer 111 which is in contact with the first channel layer 105, the heat treatment process may be performed such that the impurity concentration in the coupling channel layer 111 gradually decreases in a direction toward the upper surface of the coupling channel layer 111 from the region in contact with the first channel layer 105. Alternatively, when the above-described ion implantation process is performed to inject the impurity to target the upper region of the coupling channel layer 111, the heat treatment process may be performed such that the impurity concentration in the coupling channel layer 111 gradually increases in a direction toward the upper surface of the coupling channel layer 111 from the region in contact with the first channel layer 105.

The coupling channel layer 111 and the third core layer 113 may be defined as a coupling structure.

Referring to FIG. 5D, a second stacked structure ST2 may be formed by stacking third material layers 115 and fourth material layers 117 alternately with each other over the insulating layer 109 and coupling structures each including the coupling channel layer 111 and the third core layer 113. The third material layers 115 may include a different material from the fourth material layers 117. For example, the third material layers 115 may include the same material as the first material layers 101 and the fourth material layers 117 may include the same material as the second material layers 103.

Subsequently, second channel holes H2 passing through the second stacked structure ST2 may be formed by partially etching the third material layers 115 and the fourth material layers 117. In an embodiment, each of the second channel holes H2 may be formed to expose an upper part of the coupling structures each including the coupling channel layer 111 and the third core layer 113. Furthermore, in an embodiment, each of the second channel holes H2 may be formed to expose at least part of an upper surface of the coupling channel layer 111.

Referring to FIG. 5E, a second channel layer 119 may be formed along a sidewall of each of the second channel holes H2. The second channel layer 119 may include polysilicon having an impurity. For example, the second channel layer 119 may be formed by depositing a polysilicon layer along the sidewall of each of the second channel holes H2, and dopant gas may be injected during a deposition process. The dopant gas may include arsenic (As) or phosphorus (P). The impurity included in the second channel layer 119 may be the same as the impurity included in the first channel layer 105.

Subsequently, a second core layer 121 may be formed to fill a central part of each of the second channel holes H2. The second core layer 121 may include an oxide layer. The second channel layer 119 and the second core layer 121 may be defined as a second vertical structure.

A process of forming a memory layer (not shown) along the sidewall of each of the second channel holes H2 may be performed before the above-described process of forming the second channel layer 119 is performed. The memory layer (not shown) may include a charge trapping layer that is capable of trapping charges.

Referring to FIG. 5F, a slit SLIT passing through the first stacked structure ST1 and the second stacked structure ST2 may be formed to expose sidewalls of the first material layers 101 shown in FIG. 5E of the first stacked structure ST1 and sidewalls of the third material layers 115 shown in FIG. 5E of the second stacked structure ST2.

Subsequently, the first material layers 101 shown in FIG. 5E and the third material layers 115 shown in FIG. 5E that are exposed by the slit SLIT may be removed and electrode patterns 123 may be formed in spaces from which the first material layers 101 shown in FIG. 5E and the third material layers 115 shown in FIG. 5E are removed. The electrode patterns 123 may include one or more of a doped silicon layer, a metal silicide layer, a metal layer, and a metal nitride layer.

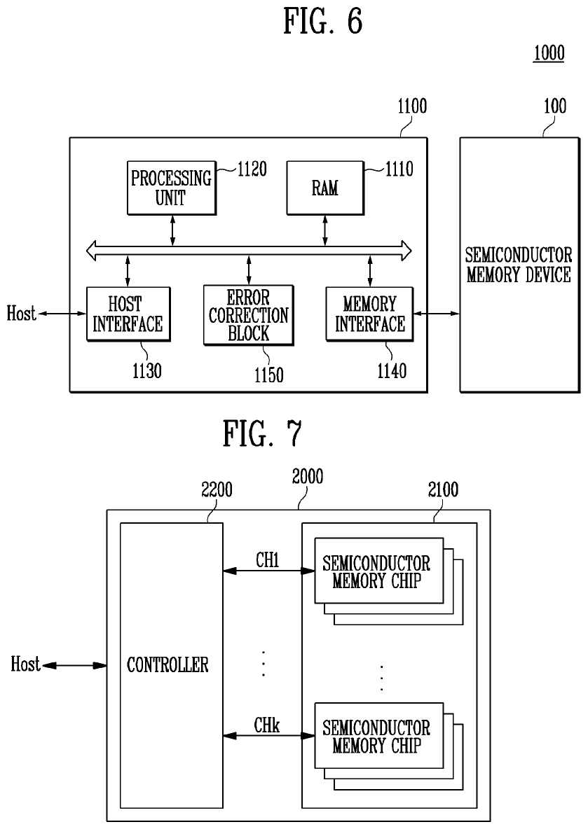

FIG. 6 is a block diagram illustrating a memory system 1000 including the semiconductor memory device shown in FIG. 1.

Referring to FIG. 6, the memory system 1000 may include the semiconductor memory device 100 and a controller 1100.

The semiconductor memory device 100 may be configured and operated in substantially the same manner as described above with reference to FIG. 1. Hereinafter, repetitive explanations will be omitted.

The controller 1100 may be coupled to a host Host and the semiconductor memory device 100. The controller 1100 may be configured to access the semiconductor memory device 100 in response to a request from the host Host. For example, the controller 1100 may be configured to control a read operation, a program operation, an erase operation, and a background operation of the semiconductor memory device 100. The controller 1100 may be configured to provide an interface between the semiconductor memory device 100 and the host Host. The controller 1100 may be configured to drive firmware for controlling the semiconductor memory device 100.

The controller 1100 may include Random Access Memory (RAM) 1110, a processing unit 1120, a host interface 1130, a memory interface 1140, and an error correction block 1150. The RAM 1110 may be used as at least one of operating memory of the processing unit 1120, cache memory between the semiconductor memory device 100 and the host Host, and buffer memory between the semiconductor memory device 100 and the host Host. The processing unit 1120 may control general operations of the controller 1100. In addition, the controller 1100 may temporarily store program data provided from the host Host during a write operation.

The host interface 1130 may include a protocol for exchanging data between the host Host and the controller 1100. In an embodiment, the controller 1100 may communicate with the host Host through at least one of various interface protocols such as a Universal Serial Bus (USB) protocol, a MultiMedia Card (MMC) protocol, a Peripheral Component Interconnect (PCI) protocol, a PCI Express (PCI-e) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, an Integrated Drive Electronics (IDE) protocol, and a private protocol.

The memory interface 1140 may interface with the semiconductor memory device 100. For example, the memory interface 1140 may include a NAND interface or a NOR interface.

The error correction block 1150 may detect and correct errors in data received from the semiconductor memory device 100 by using an error correction code (ECC). The processing unit 1120 may control the semiconductor memory device 100 to control a read voltage and perform re-read according to an error detection result of the error correction block 1150. According to an embodiment, the error correction block 1150 may be provided as one of the components of the controller 1100.

The controller 1100 and the semiconductor memory device 100 may be integrated into a single semiconductor device. According to an embodiment, the controller 1100 and the semiconductor memory device 100 may be integrated into a single semiconductor device to form a memory card. For example, the controller 1100 and the semiconductor memory device 100 may be integrated into a single semiconductor device and form a memory card such as a personal computer memory card international association (PCMCIA), a compact flash (CF) card, a smart media card (SM or SMC), a memory stick, a multimedia card in the form of a multimedia card (MMC), a Reduced-Size MMC (RS-MMC), or a micro-MMC, a secure digital card in the form of a secure digital (SD) card, a mini-SD card, a micro-SD card, or a SD High Capacity (SDHC) card, and Universal Flash Storage (UFS).

The controller 1100 and the semiconductor memory device 100 may be integrated into a single semiconductor device to form a Solid State Drive (SSD). The SSD may include a storage device configured to store data in semiconductor memory. When the memory system 1000 is used as the SSD, in an embodiment, operational rates of the host Host coupled to the memory system 1000 may be significantly improved.

In another example, the memory system 1000 may be provided as one of various elements of an electronic device such as a computer, a ultra-mobile PC (UMPC), a workstation, a net-book, a personal digital assistant (PDA), a portable computer, a web tablet, a wireless phone, a mobile phone, a smartphone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various electronic devices for forming a home network, one of various electronic devices for forming a computer network, one of various electronic devices for forming a telematics network, an RFID device, or one of various elements for forming a computing system.

According to an embodiment, the semiconductor memory device 100 or the memory system 1000 may be embedded in packages of various forms. For example, the semiconductor memory device 100 or the memory system 1000 may be embedded in packages such as a Package on Package (POP), Ball Grid Arrays (BGAs), Chip Scale Packages (CSPs), a Plastic Leaded Chip Carrier (PLCC), a Plastic Dual In-line Package (PDIP), a Die in Waffle Pack, a Die in Wafer Form, a Chip On Board (COB), a Ceramic Dual In-line Package (CERDIP), a Plastic Metric Quad Flat Pack (MQFP), a

Thin Quad Flat Pack (TQFP), a Small Outline Integrated Circuit (SOIC), a Shrink Small Outline Package (SSOP), a Thin Small Outline Package (TSOP), a System In Package (SIP), a Multi-Chip Package (MCP), a Wafer-level Fabricated Package (WFP), or a Wafer-level Processed Stack Package (WSP).

FIG. 7 is a block diagram illustrating an example of application of the memory system shown in FIG. 6.

Referring to FIG. 7, a memory system 2000 may include a semiconductor memory device 2100 and a controller 2200. The semiconductor memory device 2100 may include a plurality of fsemiconductor memory chips. The plurality of semiconductor memory chips may be divided into a plurality of groups.

FIG. 7 illustrates that the plurality of groups communicate with the controller 2200 through first to kth channels CH1 to CHk, respectively. Each of the semiconductor memory chips may be configured and operated in substantially the same manner as the semiconductor memory device 100 described above with reference to FIG. 1.

Each group may be configured to communicate with the controller 2200 through a single common channel. The controller 2200 may be configured in substantially the same manner as the controller 1100 described above with reference to FIG. 6, and configured to control the plurality of memory chips of the semiconductor memory device 2100 through the plurality of channels CH1 to CHk.

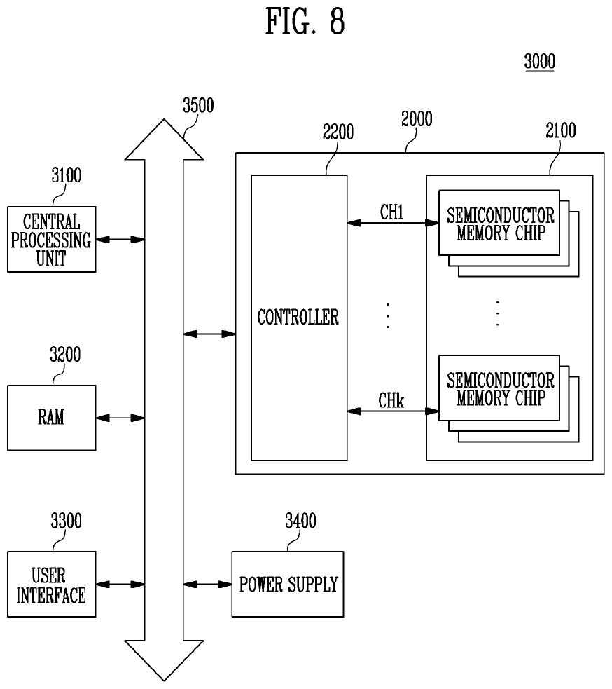

FIG. 8 is a block diagram illustrating a computing system 3000 having the memory system 2000 described above with reference to FIG. 7.

Referring to FIG. 8, the computing system 3000 may include a central processing unit 3100, Random Access Memory (RAM) 3200, a user interface 3300, a power supply 3400, a system bus 3500, and the memory system 2000.

The memory system 2000 may be electrically coupled to the central processing unit 3100, the RAM 3200, the user interface 3300, and the power supply 3400 through the system bus 3500. Data provided through the user interface 3300 or data processed by the central processing unit 3100 may be stored in the memory system 2000.

FIG. 8 illustrates that the semiconductor memory device 2100 is coupled to the system bus 3500 through the controller 2200. However, the semiconductor memory device 2100 may be configured to be directly coupled to the system bus 3500. When the semiconductor memory device 2100 is configured to be directly coupled to the system bus 3500, the functions of the controller 2200 may be performed by the central processing unit 3100 and the RAM 3200.

Referring to FIG. 8, it is illustrated that the memory system 2000 described with reference to FIG. 7 is provided. However, in FIG. 8, the memory system 2000 may be replaced with the memory system 1000 described with reference to FIG. 6. According to an embodiment, the computing system 3000 may include both of the memory systems 1000 and 2000 described above with reference to FIGS. 6 and 7, respectively.

According to embodiments of the present disclosure, electrical characteristics of a semiconductor memory device may be improved by adjusting an impurity concentration of a channel of a memory string.

What is claimed is:

1. A semiconductor memory device, comprising:
a first stacked structure including a plurality of first electrode patterns and a plurality of first interlayer insulating layers that are alternately stacked on each other;
a first vertical structure extending into the first stacked structure in a vertical direction;
an insulating layer formed over the first stacked structure;
a coupling structure passing through the insulating layer and formed over the first vertical structure;
a second stacked structure including a plurality of second electrode patterns and a plurality of second interlayer insulating layers that are alternately stacked on each other over the insulating layer; and
a second vertical structure extending into the second stacked structure in the vertical direction and formed over the coupling structure,
wherein each of the first vertical structure, the coupling structure, and the second vertical structure includes an impurity, and
wherein a concentration of the impurity of the coupling structure varies depending on proximity to one of the first vertical structure and the second vertical structure.

2. The semiconductor memory device of claim 1, wherein the first vertical structure includes a first core layer and a first channel layer, the first core layer extending in the vertical direction, the first channel layer surrounding a sidewall of the first core layer and including the impurity,
wherein the coupling structure includes a third core layer and a coupling channel layer, the third core layer extending in the vertical direction, the coupling channel layer surrounding a sidewall of the third core layer and including the impurity, and
wherein the second vertical structure includes a second core layer and a second channel layer, the second core layer extending in the vertical direction, the second channel layer surrounding a sidewall of the second core layer and including the impurity.

3. The semiconductor memory device of claim 2, wherein a lower part of the coupling channel layer contacts an upper part of the first channel layer, and
wherein an upper part of the coupling channel layer contacts a lower part of the second channel layer.

4. The semiconductor memory device of claim 3, wherein a lower part of the first vertical structure is coupled to a source line and an upper part of the second vertical structure is coupled to a bit line,
wherein the first vertical structure and the plurality of first electrode patterns are defined as a first cell portion including a plurality of first memory cells, the plurality of first electrode patterns surrounding a sidewall of the first vertical structure at different levels, and
wherein the second vertical structure and the plurality of second electrode patterns are defined as a second cell portion including a plurality of second memory cells, the plurality of second electrode patterns surrounding a sidewall of the second vertical structure at different levels.

5. The semiconductor memory device of claim 4, wherein the plurality of first memory cells and the plurality of second memory cells are sequentially programmed in order from a memory cell adjacent to the source line to a memory cell adjacent to the bit line during a program operation.

6. The semiconductor memory device of claim 5, wherein the concentration of the impurity of the coupling channel layer is the highest in a region that is in contact with the first channel layer and becomes lower in a direction toward the second channel layer.

7. The semiconductor memory device of claim 4, wherein the plurality of first memory cells and the plurality of second memory cells are sequentially programmed in order from a memory cell adjacent to the bit line to a memory cell adjacent to the source line during a program operation.

8. The semiconductor memory device of claim 7, wherein the concentration of the impurity of the coupling channel layer is the highest in a region that is in contact with the second channel layer and becomes lower in a direction toward the first channel layer.

9. The semiconductor memory device of claim 2, wherein a thickness of the coupling channel layer in a horizontal direction is greater than a thickness of each of the first channel layer and the second channel layer in the horizontal direction.

10. A semiconductor memory device, comprising:
a first vertical structure including a first core layer and a first channel layer, the first core layer extending in a vertical direction, the first channel layer surrounding a sidewall of the first core layer;
a second vertical structure disposed over the first vertical structure and including a second core layer and a second channel layer, the second core layer extending in the vertical direction, the second channel layer surrounding a sidewall of the second core layer; and
a coupling structure disposed between the first vertical structure and the second vertical structure and including a third core layer and a coupling channel layer, the coupling channel layer surrounding a sidewall of the third core layer,
wherein a concentration of an impurity of the coupling channel layer is higher than a concentration of an impurity of each of the first channel layer and the second channel layer.

11. The semiconductor memory device of claim 10, wherein the concentration of the impurity of the coupling channel layer linearly increases or linearly decreases in the vertical direction.

12. The semiconductor memory device of claim 10, wherein the concentration of the impurity of the coupling channel layer increases in a direction toward the first channel layer.

13. The semiconductor memory device of claim 10, wherein the concentration of the impurity of the coupling channel layer increases in a direction toward the second channel layer.

14. The semiconductor memory device of claim 10, wherein a thickness of the coupling channel layer in a horizontal direction is greater than a thickness of each of the first channel layer and the second channel layer in the horizontal direction.

15. The semiconductor memory device of claim 10, further comprising a plurality of electrode patterns surrounding a sidewall of the first vertical structure and a sidewall of the second vertical structure at different levels.

16. A method of manufacturing a semiconductor memory device, the method comprising:
forming a first stacked structure by stacking first material layers and second material layers alternately with each other;
forming first channel holes that pass through the first stacked structure in a vertical direction and forming a first channel layer that includes an impurity and is disposed on a sidewall of each of the first channel holes;
forming an insulating layer that is disposed over the first stacked structure and the first channel layer and forming coupling holes that pass through the insulating layer and expose the first channel layer;
forming a coupling channel layer on a sidewall of each of the coupling holes, wherein a lower part of the coupling channel layer is formed to be in contact with an upper surface of the first channel layer;
injecting the impurity into the coupling channel layer by performing an ion implantation process;
forming a second stacked structure by stacking third material layers and fourth material layers alternately with each other over the insulating layer and the coupling channel layer; and
forming second channel holes that pass through the second stacked structure in the vertical direction and expose an upper surface of the coupling channel layer and forming a second channel layer that includes the impurity and is disposed on a sidewall of each of the second channel holes,
wherein, in injecting the impurity into the coupling channel layer, the ion implantation process is performed such that a concentration of the impurity of the coupling channel layer is higher than a concentration of the impurity of each of the first channel layer and the second channel layer.

17. The method of claim 16, wherein, in injecting the impurity into the coupling channel layer, a heat treatment process is performed after injecting the impurity by performing the ion implantation process to target a lower region of the coupling channel layer that is adjacent to the first channel layer.

18. The method of claim 17, wherein the concentration of the impurity in the coupling channel layer is adjusted by performing the heat treatment process, such that the concentration of the impurity in the coupling channel layer becomes higher in a direction toward the first channel layer and becomes lower in a direction toward the second channel layer.

19. The method of claim 16, wherein, in injecting the impurity into the coupling channel layer, a heat treatment process is performed after injecting the impurity by performing the ion implantation process to target an upper region of the coupling channel layer that is adjacent to the second channel layer.

20. The method of claim 19, wherein the concentration of the impurity in the coupling channel layer is adjusted by performing the heat treatment process, such that the concentration of the impurity in the coupling channel layer becomes higher in a direction toward the second channel layer and becomes lower in a direction toward the first channel layer.
